(19) United States
(12) Patent Application Publication
(10) Pub. No.: US 2025/0221232 A1
(43) Pub. Date: Jul. 3, 2025

(54) Light Emitting Display Apparatus

(71) Applicant: LG Display Co., Ltd., Seoul (KR)

(72) Inventors: Minki Kim, Paju-si (KR); Hyemin Hwang, Paju-si (KR); Beomgon Jo, Paju-si (KR); Jaehwan Myung, Paju-si (KR)

(21) Appl. No.: 18/917,936

(22) Filed: Oct. 16, 2024

(30) Foreign Application Priority Data
Dec. 29, 2023 (KR) 10-2023-0197254

(51) Int. Cl. H10K 59/60; G02B 27/01; H10K 59/80; H10K 102/00

(52) U.S. Cl. CPC H10K 59/60; H10K 59/878; G02B 27/0172; G02B 2027/0178; H10K 2102/3031; H10K 2102/351

(57) ABSTRACT

A light emitting display apparatus is presented herein in which a solar cell is integrated into a light emitting display panel. The light emitting display apparatus comprising a pixel driving circuit layer including a plurality of pixel driving circuits; a planarization layer that covers the pixel driving circuit layer; a solar cell on the planarization layer; an insulation layer on the solar cell; a selective reflecting metal in the insulation layer, the selective reflecting metal including at least three metal layers; and a plurality of light emitting devices on the insulation layer.

### CROSS-REFERENCE TO RELATED APPLICATIONS

This application claims priority from Republic of Korea Patent Application No. 10-2023-0197254, filed on Dec. 29, 2023, which is hereby incorporated by reference in its entirety.

### BACKGROUND

### Field

The present disclosure relates to a light emitting display apparatus.

### Discussion of Related Art

Light emitting display apparatuses are mounted on or provided in electronic products such as televisions, monitors, notebook computers, smart phones, tablet computers, electronic pads, wearable devices, watch phones, portable information devices, navigation devices, or vehicle control display devices, etc., to display images.

A user can carry and use an electronic product equipped with a light emitting display apparatus.

Therefore, the lifespan and weight reduction of a battery of a light emitting display apparatus are becoming an important issue.

### SUMMARY

Accordingly, the present disclosure is directed to providing a light emitting display apparatus that substantially obviates one or more problems due to limitations and disadvantages of the related art.

Embodiments of the present disclosure are directed to providing a light emitting display apparatus in which a solar cell is integrated into a light emitting display panel.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other advantages and in accordance with the purpose of the disclosure, as embodied and broadly described herein, there is provided a light emitting display apparatus comprising a pixel driving circuit layer including a plurality of pixel driving circuits; a planarization layer that covers the pixel driving circuit layer; a solar cell on the planarization layer; an insulation layer on the solar cell; a selective reflecting metal in the insulation layer, the selective reflecting metal including at least three metal layers; and a plurality of light emitting devices on the insulation layer.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate embodiments of the disclosure and together with the description serve to explain the principle of the disclosure. In the drawings:

FIG. 1 is a diagram illustrating a configuration of a light emitting display apparatus according to one or more embodiments of the present disclosure;

FIG. 2 is a diagram illustrating a structure of a pixel applied to a light emitting display apparatus according to one or more embodiments of the present disclosure;

FIG. 3 is a diagram illustrating a structure of a control driver applied to a light emitting display apparatus according to one or more embodiments of the present disclosure;

FIG. 4 is a diagram illustrating a structure of a gate driver applied to a light emitting display apparatus according to one or more embodiments of the present disclosure;

FIG. 5 is a diagram illustrating a structure of a data driver applied to a light emitting display apparatus according to one or more embodiments of the present disclosure;

FIG. 6 is a diagram illustrating a cross-sectional surface of a light emitting display panel applied to a light emitting display apparatus according to one or more embodiments of the present disclosure;

FIG. 7 is a diagram illustrating reflection characteristics of a selective reflecting metal applied to a light emitting display apparatus according to one or more embodiments of the present disclosure;

FIG. 8 is a diagram illustrating transmission characteristics of a selective reflecting metal applied to a light emitting display apparatus according to one or more embodiments of the present disclosure;

FIGS. 9 to 11 are other diagrams illustrating a cross-sectional surface of a light emitting display panel applied to a light emitting display apparatus according to one or more embodiments of the present disclosure; and

FIG. 12 is another diagram illustrating a cross-section surface of a light emitting display panel applied to a light emitting display apparatus according to one or more embodiments of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present disclosure are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. can be used. These terms are intended to identify the corresponding elements from the other elements, and basis, order, or number of the corresponding elements should not be limited by these terms. The expression that an element is “connected,” “coupled,” or “adhered” to another element or layer the element or layer cannot only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Also, the term “can” used herein includes all meanings and definitions of the word “may”.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, embodiments of the present disclosure will be described in detail with reference to the accompanying drawings.

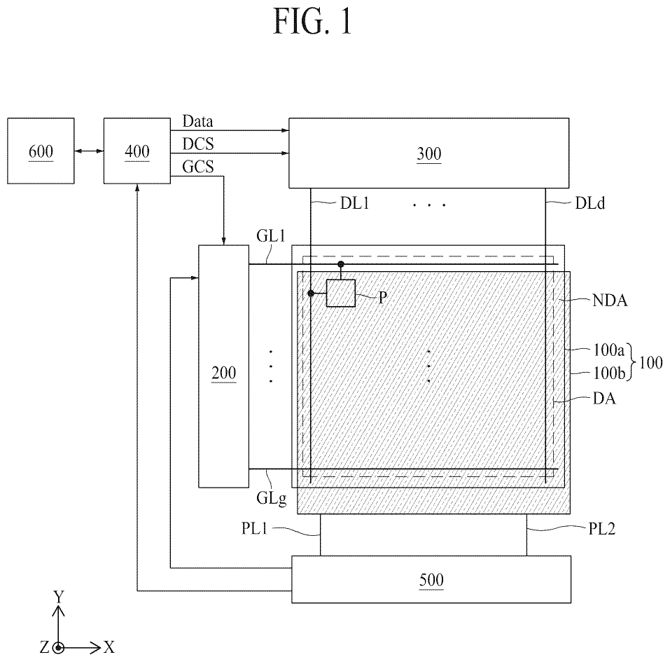

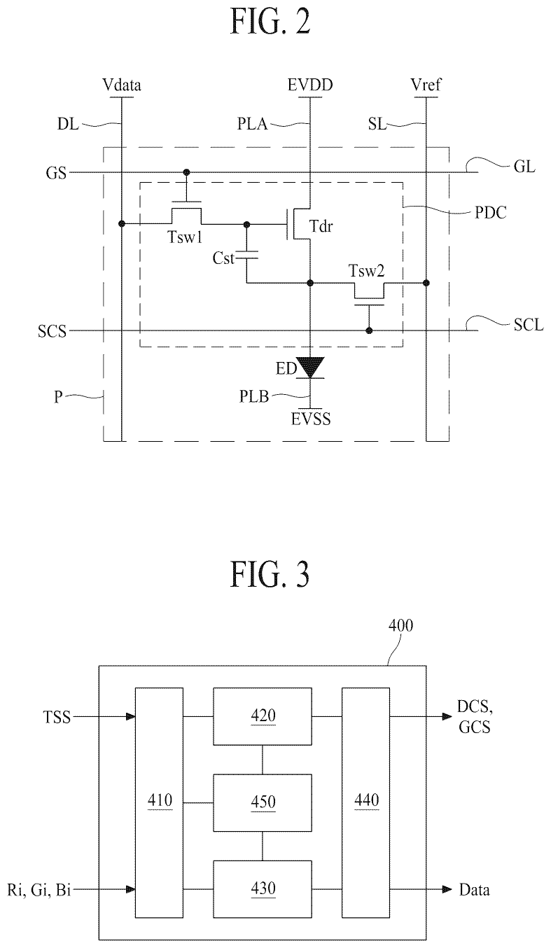

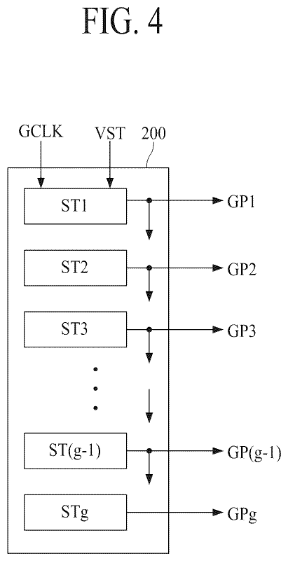

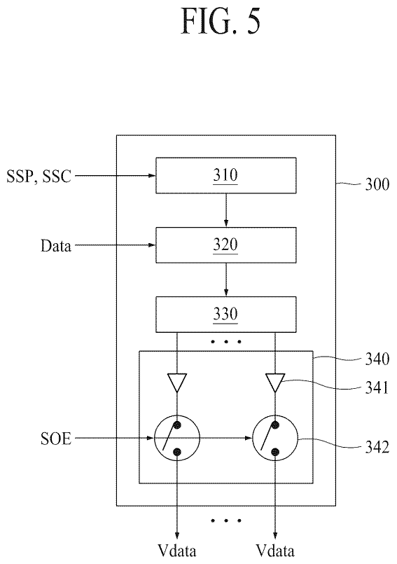

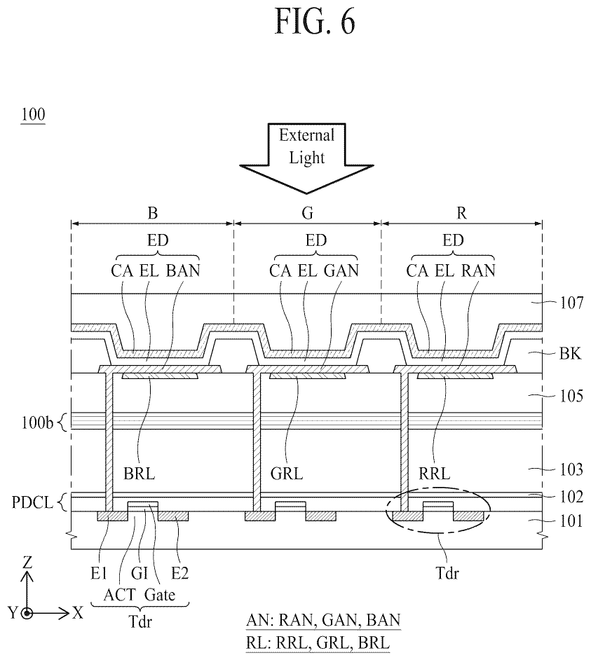

FIG. 1 is a diagram illustrating a configuration of a light emitting display apparatus according to one or more embodiments of the present disclosure, FIG. 2 is a diagram illustrating a structure of a pixel applied to a light emitting display apparatus according to one or more embodiments of the present disclosure, FIG. 3 is a diagram illustrating a structure of a control driver applied to a light emitting display apparatus according to one or more embodiments of the present disclosure, FIG. 4 is a diagram illustrating a structure of a gate driver applied to a light emitting display apparatus according to one or more embodiments of the present disclosure, and FIG. 5 is a diagram illustrating a structure of a data driver applied to a light emitting display apparatus according to one or more embodiments of the present disclosure.

A light emitting display apparatus according to one or more embodiments of the present disclosure can be used as various kinds of electronic devices. Electronic devices can be, for example, televisions, monitors, etc.

The light emitting display apparatus according to one or more embodiments of the present disclosure, as illustrated in FIG. 1, can include a light emitting display panel 100 which includes a display area DA displaying an image and a non-display area NDA provided outside the display area DA, a gate driver 200 which supplies gate signals GS to a plurality of gate lines GL1 to GLg provided in the display area DA of the light emitting display panel 100, a data driver 300 which supplies data voltages Vdata to a plurality of data lines DL1 to DLd provided in the display area DA of the light emitting display panel 100, a control driver 400 which controls driving of the gate driver 200 and the data driver 300, and a power supply unit 500 which charges power generated from a solar cell 100b provided in the light emitting display panel 100 and supplies power to the control driver 400, the gate driver 200, the data driver 300, and the light emitting display panel 100.

First, the light emitting display panel 100 includes a light emitting device unit 100a in which an image is displayed and a solar cell 100b provided in the light emitting device unit 100a and generating power by using light introduced from outside.

The light emitting device unit 100a can include a display area DA and a non-display area NDA. Gate lines GL1 to GLg, data lines DL1 to DLd, and pixels P can be provided in the display area DA. Accordingly, an image can be displayed in the display area DA. Here, g and d are natural numbers. The non-display area NDA can surround the outer periphery of the display area DA.

The pixel P included in the light emitting device unit 100a, as illustrated in FIG. 2, can include a pixel driving circuit PDC which includes a switching transistor Tsw1, a storage capacitor Cst, a driving transistor Tdr, and a sensing transistor Tsw2, and a light emitting device ED connected to the pixel driving circuit PDC.

A first terminal of the driving transistor Tdr can be connected to a first voltage supply line PLA through which a first voltage EVDD is supplied, and a second terminal of the driving transistor Tdr can be connected to the light emitting device ED.

A first terminal of the switching transistor Tsw1 can be connected to a data line DL, a second terminal of the switching transistor Tsw1 can be connected to a gate of the driving transistor Tdr, and a gate of the switching transistor Tsw1 can be connected to a gate line GL.

A data voltage Vdata can be supplied through the data line DL from the data driver 300. A gate signal GS can be supplied through the gate line GL from the gate driver 200. The gate signal GS can include a gate pulse (e.g., GP1-GPg shown in FIG. 4, which can be collectively referred to as GP) for turning on the switching transistor Tsw1 and a gate-off signal for turning off the switching transistor Tsw1.

The sensing transistor Tsw2 can be provided for measuring a threshold voltage of the driving transistor Tdr or mobility of an electrical charge (for example, an electron), or supplying a reference voltage Vref to the pixel driving circuit PDC. A first terminal of the sensing transistor Tsw2 can be connected to the second terminal of the driving transistor Tdr and the light emitting device ED, a second terminal of the sensing transistor Tsw2 can be connected to a sensing line SL through which the reference voltage Vref is supplied, and a gate of the sensing transistor Tsw2 can be connected to a sensing control line SCL through which a sensing control signal SCS is supplied.

The sensing line SL can be connected to the data driver 300 and can be connected to the power supply unit 500 through the data driver 300. For example, the reference voltage Vref supplied from the power supply unit 500 can be supplied to the pixels P through the sensing line SL, sensing signals transmitted from the pixels P can be converted into digital sensing signals in the data driver 300, and the digital sensing signals can be transmitted to the control driver 400. The light emitting device ED can include a first electrode supplied with a first voltage EVDD through the driving transistor Tdr, a second electrode connected to a second voltage supply line PLB through which a second voltage is supplied, and a light emitting layer provided between the first electrode and the second electrode. The first electrode can be an anode and the second electrode can be a cathode.

The structure of the pixel P applied to a light emitting display apparatus according to one or more embodiments of the present disclosure is not limited to the structure illustrated in FIG. 2. Accordingly, the structure of the pixel P can be changed to various shapes.

The solar cell 100b performs a function of generating power by using light introduced from outside, and for this purpose, the solar cell 100b includes an acceptor formed of a P-type semiconductor and a donor formed of an N-type semiconductor.

In this case, the acceptor can be connected to the power supply unit 500 through a first electrode line PL1, and the donor can be connected to the power supply unit 500 through a second electrode line PL2.

The control driver 400 can realign input image data Ri, Gi, and Bi transmitted from an external system 600 by using a timing synchronization signal TSS transmitted from the external system 600 and can generate a data control signal DCS which is to be supplied to the data driver 300 and a gate control signal GCS which is to be supplied to the gate driver 200.

To this end, as illustrated in FIG. 3, the control driver 400 can include a data aligner 430 which realigns input image data Ri, Gi, and Bi to generate image data Data, a control signal generator 420 which generates the gate control signal GCS and the data control signal DCS by using the timing synchronization signal TSS, an input unit 410 which transmits the timing synchronization signal TSS transmitted from the external system 600 to the control signal generator 420 and transmits the input image data Ri, Gi, and Bi transmitted from the external system 600 to the data aligner 430, and an output unit 440 which supplies the data driver 300 with the image data Data generated by the data aligner 430 and the data control signal DCS generated by the control signal generator 420 and supplies the gate driver 200 with the gate control signal GCS generated by the control signal generator 420.

The control signal generator 420 can generate a power control signal supplied to the power supply unit 500.

The control driver 400 can further include a storage unit for storing various information. The storage unit 450 can be included in the control driver 400 as illustrated in FIG. 3, but can be separated from the control driver 400 and provided independently.

The external system 600 can perform a function of driving the control driver 400 and an electronic device.

For example, when the electronic device is a television (TV), the external system 600 can receive various kinds of sound information and image information over a communication network and can transmit the received image information to the control driver 400. For example, the external system 600 can convert the image information into input image data Ri, Gi, and Bi and transmit the input image data Ri, Gi, and Bi to the control driver 400.

The power supply unit 500 charges the power generated and transmitted from the solar cell, and supplies the charged power to the control driver 400, the gate driver 200, the data driver 300, and the light emitting device unit 100a. That is, the power supply unit 500 can function as a rechargeable battery or a battery.

Moreover, the power supply unit 500 can supply power supplied from an external power supply to the control driver 400, the gate driver 200, the data driver 300, and the light emitting device unit 100a.

The gate driver 200 can be directly embedded into the non-display area NDA by using a gate-in panel (GIP) type, or the gate driver 200 can be provided in the display area DA in which light emitting devices ED are provided, or the gate driver 200 can be provided on a chip on film mounted in the non-display area NDA.

The gate driver 200 can supply gate pulses GP1 to GPg to the gate lines GL1 to GLg.

When a gate pulse GP generated by the gate driver 200 is supplied to a gate of the switching transistor Tsw1 included in the pixel P, the switching transistor Tsw1 can be turned on. When the switching transistor Tsw1 is turned on, data voltage Vdata supplied through a data line DL can be supplied to the pixel P.

When a gate-off signal generated by the gate driver 200 is supplied to the switching transistor Tsw1, the switching transistor Tsw1 can be turned off. When the switching transistor Tsw1 is turned off, a data voltage cannot be supplied to the pixel P any longer.

The gate signal GS supplied to the gate line GL can include the gate pulse GP and the gate-off signal.

To supply gate pulses GP1 to GPg to gate lines GL1 to GLg, the gate driver 200, as illustrated in FIG. 4, can include stages ST1 to STg connected to gate lines GL1 to GLg.

Each of the stages ST1 to STg can be connected to one gate line GL, but can be connected to at least two gate lines GL.

In order to generate gate pulses GP1 to GPg, a gate start signal VST and at least one gate clock GCLK which are generated by the control signal generator 420 can be transferred to the gate driver 200. For example, the gate start signal VST and the at least one gate clock GCLK can be included in the gate control signal GCS.

One of the stages ST1 to STg can be driven by a gate start signal VST to output a gate pulse GP to a gate line GL. The gate pulse GP can be generated by a gate clock GCLK.

At least one of signals output from a stage ST where a gate pulse is output can be supplied to another stage ST to drive another stage ST. Accordingly, a gate pulse can be output in another stage ST.

For example, the stages ST can be driven sequentially to sequentially supply the gate pulses GP to the gate lines GL.

The data driver 300 can supply data voltages Vdata to the data lines DL1 to DLd.

To this end, the data driver 300, as illustrated in FIG. 5, can include a shift register 310 which outputs a sampling signal, a latch 320 which latches image data Data received from the control driver 400, a digital-to-analog converter 330 which converts the image data Data, transmitted from the latch 320, into a data voltage Vdata and outputs the data voltage Vdata, and an output buffer 340 which outputs the data voltage, transmitted from the digital-to-analog converter 330, to the data line DL on the basis of a source output enable signal SOE.

The shift register 310 can output the sampling signal by using the data control signal DCS received from the control signal generator 420. For example, the data control signals DCS transmitted to the shift register 310 can include a source start pulse SSP and a source shift clock signal SSC.

The latch 320 can latch image data Data sequentially received from the control driver 400, and then output the image data Data to the digital-to-analog converter 330 at the same time on the basis of the sampling signal.

The digital-to-analog converter 330 can convert the image data Data transmitted from the latch 320 into data voltages Vdata and output the data voltages Vdata.

The output buffer 340 can simultaneously output the data voltages Vdata transmitted from the digital-to-analog converter 330 to data lines DL1 to DLd of the light emitting display panel 100 on the basis of the source output enable signal SOE transmitted from the control signal generator 420.

To this end, the output buffer 340 can include a buffer 341 which stores the data voltage Vdata transmitted from the digital-to-analog converter 330 and a switch 342 which outputs the data voltage Vdata stored in the buffer 341 to the data line DL on the basis of the source output enable signal SOE.

For example, when the switches 342 are turned on based on the source output enable signal SOE simultaneously supplied to the switches 342, the data voltages Vdata stored in the buffers 341 can be supplied to the data lines DL1 to DLd through the switches 342.

The data voltages Vdata supplied to the data lines DL1 to DLd can be supplied to pixels P connected to a gate line GL supplied with a gate pulse GP.

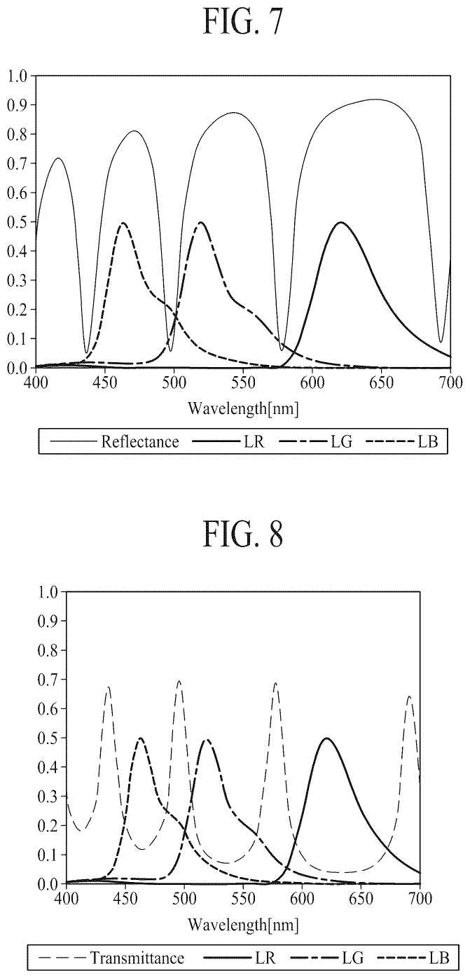

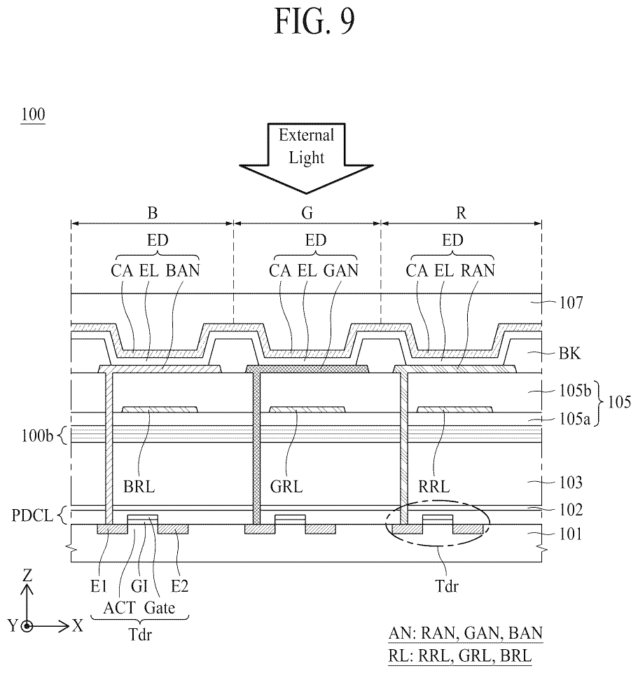

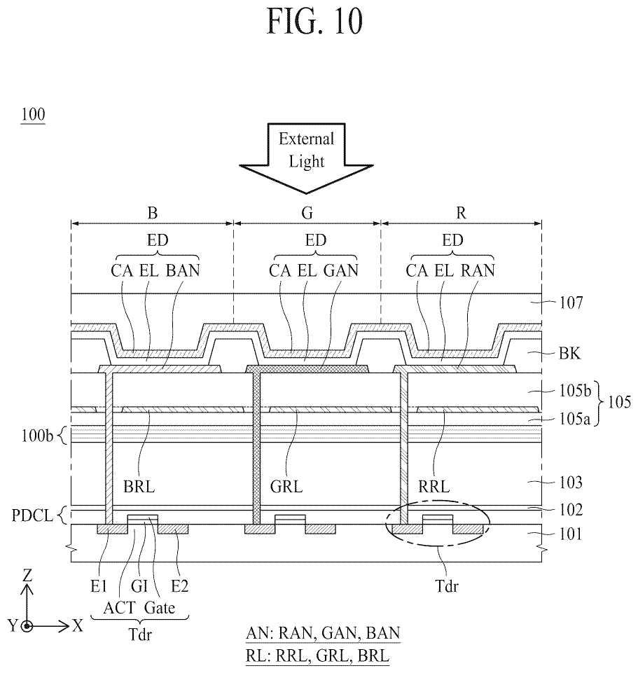

FIG. 6 is a diagram illustrating a cross-sectional surface of a light emitting display panel applied to a light emitting display apparatus according to one or more embodiments of the present disclosure, FIG. 7 is a diagram illustrating reflection characteristics of a selective reflecting metal applied to a light emitting display apparatus according to one or more embodiments of the present disclosure, and FIG. 8 is a diagram illustrating transmission characteristics of a selective reflecting metal applied to a light emitting display apparatus according to one or more embodiments of the present disclosure. Particularly, FIG. 6 is a diagram illustrating a cross-sectional surface of an area including a blue pixel B, a green pixel G, and a red pixel R, FIG. 7 is a diagram illustrating a ratio at which blue light LB, green light LG, and red light LR generated in the blue pixel B, the green pixel G, and the red pixel R are reflected in the selective reflecting metal RL, and FIG. 8 is a diagram illustrating a ratio at which blue light LB, green light LG, and red light LR generated in the blue pixel R, the green pixel G, and the red pixel R are transmitted in the selective reflecting metal RL. In the following descriptions, details which are the same as or similar to details described with reference to FIGS. 1 to 5 will be omitted or briefly described.

As illustrated in FIG. 6, a light emitting display panel 100 including a substrate 101 provided with a semiconductor can be applied to a light emitting display apparatus according to one or more embodiments of the present disclosure.

A small light emitting display panel can be applied to virtual reality (VR) devices and augmented reality (AR) devices, and for example, a light emitting display panel 100 including a substrate 101 formed of semiconductor can be applied.

The light emitting display panel 100 including the substrate 101 formed of semiconductor can be referred to as an organic light emitting display on silicon (OLEDoS).

The size of the light emitting display panel applied to virtual reality (VR) devices and augmented reality (AR) devices is much smaller than that of the light emitting display panel applied to electronic devices such as televisions, monitors, and smartphones.

Therefore, the light emitting display panel applied to virtual reality (VR) devices and augmented reality (AR) devices can be manufactured by using the substrate 101 formed of semiconductors which are advantageous for miniaturization.

For example, a substrate 101 formed of semiconductors can be a silicon substrate formed through a complementary metal oxide semiconductor (CMO) process or a germanium substrate.

A light emitting display apparatus using a substrate 101 formed of semiconductor can be applied to electronic products such as virtual reality (VR) devices and augmented reality (AR) devices manufactured in a form of glasses, for example.

When a light emitting display apparatus according to one or more embodiments of the present disclosure is applied to an electronic product, such as a virtual reality (VR) device and an augmented reality (AR) device manufactured in the form of glasses, charging by a solar cell can be performed together when the electronic product is used. Therefore, a user can use a virtual reality (VR) device and an augmented reality (AR) device in the form of glasses for a long time without charging.

In this case, because the virtual reality (VR) device and augmented reality (AR) device do not need to be connected to a battery, the virtual reality (VR) device and augmented reality (AR) device do not need to be connected to a wire to connect the virtual reality (VR) device and the augmented reality (AR) device to a battery.

Therefore, the user can experience virtual reality (VR) and augmented reality (AR) for a long time using only virtual reality (VR) devices and augmented reality (AR) devices in the form of glasses without auxiliary devices such as batteries and wires.

However, a light emitting display apparatus according to one or more embodiments of the present disclosure is not applied only to virtual reality (VR) devices and augmented reality (AR) devices manufactured in the form of glasses.

For example, a light emitting display apparatus according to one or more embodiments of the present disclosure can be applied to an electronic product that can be carried by a user, such as a smartphone, a tablet computer, an electronic pad, a wearable device, and a watch phone. In this case, the user can use the electronic product for a long time without charging the electronic product.

Moreover, a light emitting display apparatus according to one or more embodiments of the present disclosure can be applied not only to electronic products that can be carried by the user, but also to various types of electronic products that can be placed in a place where light that can be introduced into a solar cell and generate power is supplied.

Therefore, the substrate 101 applied to a light emitting display panel 100 does not necessarily have to be a substrate formed of a semiconductor.

In other words, the function of generating power required to drive the light emitting display panel 100 by using the light emitting display panel 100 provided with the solar cell 100b can be performed not only in a light emitting display apparatus using a semiconductor substrate 101 but also in a light emitting display apparatus using a glass substrate, a plastic substrate, or a flexible substrate.

Accordingly, a light emitting display apparatus according to one or more embodiments of the present disclosure can be configured using the substrate 101 formed of semiconductors, or can be configured using a glass substrate, a plastic substrate, a flexible substrate, or a transparent substrate. The transparent substrate can be formed of a glass substrate, a plastic substrate, or a flexible substrate.

However, hereinafter, for convenience of description, referring to FIGS. 6 to 11, a light emitting display apparatus using a substrate 101 formed of a semiconductor is described as an example of the present disclosure.

A light emitting display panel 100 applied to a light emitting display apparatus according to one or more embodiments of the present disclosure includes, as illustrated in FIG. 6, a pixel driving circuit layer PDCL including the pixel driving circuits PDC, a planarization layer 103 covering the pixel driving circuit layer PDCL, a solar cell 100b disposed on the planarization layer 103, an insulation layer 105 disposed on the solar cell 100b, a selective reflecting metal RL disposed on the insulation layer 105, and light emitting devices ED disposed on the insulation layer 105. The selective reflecting metal RL can include at least three layers. The pixel driving circuit layer PDCL can be disposed on a substrate 101.

To provide a more detailed description, the light emitting display panel 100 applied to a light emitting display apparatus according to one or more embodiments of the present disclosure can include the substrate 101, the pixel driving circuit layer PDCL provided on the substrate 101, the planarization layer 103 covering the pixel driving circuit layer PDCL, the insulation layer 105 provided on the planarization layer 103, a first anode RAN, a second anode GAN, and a third anode BAN provided on the insulation layer 105, a bank BK provided between two anodes AN, a light emitting layer EL covering the anodes BAN, GAN, and RAN and the bank BK, a cathode CA covering the light emitting layer EL, and an encapsulation layer 107 covering the cathode CA.

The first anode RAN can be an anode provided in a pixel which outputs light of one color among red, green, and blue. The second anode GAN can be an anode provided in a pixel which outputs light of one color among red, green, and blue, and can be an anode provided in a pixel which outputs light of a color different from that of the first anode RAN and a third anode BAN. The third anode BAN can be an anode provided in a pixel which outputs light of one color of red, green, and blue, and can be an anode provided in a pixel which outputs light of a color different from that of the first anode RNA and the second anode GAN.

For example, the first anode RAN can be a red anode RAN provided in a red pixel R which outputs red light, the second anode GAN can be a green anode GAN provided in a green pixel G which outputs green light, and the third anode BAN can be a blue anode BAN provided in a blue pixel B which outputs blue light.

However, each of the first anode RAN, the second anode GAN, and the third anode BAN is not limited to an anode used to generate light of one specific color, but can be an anode used to generate any one of various colors.

Hereinafter, for convenience of description, the first anode, the second anode, and the third anode can be described using the reference numerals of the red anode RAN, the green anode GAN, and the blue anode BAN, and in particular, a light emitting display apparatus according to one or more embodiments of the present disclosure is described using the red anode RAN, the green anode GAN, and the blue anode BAN.

However, in the following description, when the red anode RAN or the first anode RAN, the green anode GAN or the second anode GAN, and the blue anode BAN or the third anode BAN need not be distinguished, the red anode RAN or the first anode RAN, the green anode GAN or the second anode GAN, and the blue anode BAN or the third anode BAN can be represented as the anode AN.

First, the substrate 101 can be composed of a semiconductor, as described above, and can be, for example, a silicon substrate or a germanium substrate.

Next, the pixel driving circuit layer PDCL can be provided on the substrate 101. The pixel driving circuit layer PDCL can include the transistors Tsw1, Tsw2, and Tdr and the capacitor Cst described with reference to FIG. 2.

That is, the transistors Tsw1, Tsw2, and Tdr and the capacitor Cst described with reference to FIG. 2 can be provided on the substrate 101.

For example, in FIG. 6, a light emitting display panel 100 having only driving transistors Tdr in the pixel driving circuit layer PDCL is illustrated, but in addition to the driving transistor Tdr, various transistors and capacitors can be further provided in the pixel driving circuit layer PDCL.

The pixel driving circuit layer PDCL can include at least one electrode layer and at least one insulation layer.

For example, as illustrated in FIG. 6, when the driving transistor Tdr includes the first electrode E1, the second electrode E2, the active ACT, the gate insulation layer GI, and the gate electrode Gate, the pixel driving circuit layer PDCL can include a first electrode layer provided with the first electrode E1 and the second electrode E2, a second electrode layer provided with the gate electrode Gate, a first insulation layer provided with the gate insulation layer GI, and a second insulation layer provided with a passivation layer 102 covering the driving transistor Tdr.

The first electrode E1 and the second electrode E2 can be formed by implanting impurities into the substrate 101. For example, the first electrode E1 and the second electrode E2 can be formed by implanting N-type impurities such as phosphorus (P) or arsenic (As) into the substrate 101, or by implanting P-type impurities such as boron (B) into the substrate 101.

The active ACT refers to a semiconductor provided between the first electrode E1 and the second electrode E2, and thus a portion of the substrate 101 can be used as the active ACT.

The gate insulation layer GI can be formed of silicon oxide.

The gate electrode Gate can be a doped semiconductor material, or can be a metal material such as aluminum and tungsten.

The passivation layer 102 can cover transistors provided in the pixel driving circuit layer PDCL to protect the transistors. In this case, various metal lines connected to the pixel driving circuit layer PDCL can be provided at an upper end of the passivation layer 102 or inside the passivation layer 102. To this end, the passivation layer 102 can be formed of at least one layer.

Next, the planarization layer 103 can perform a function of planarizing the upper end of the pixel driving circuit layer PDCL. The planarization layer 103 can be formed of at least one of various types of organic layers, can be formed of at least one of various types of inorganic layers, or can be formed of at least one organic layer and at least one inorganic layer.

Next, the solar cell 100b can be provided on the planarization layer 103. The solar cell 100b can include at least two layers.

For example, the solar cell 100b can include an acceptor formed of a P-type semiconductor and a donor formed of an N-type semiconductor. In this case, the acceptor can be connected to the power supply unit 500 through the first electrode line PL1, and the donor can be connected to the power supply unit 500 through the second electrode line PL2.

The acceptor can be formed of a P-type semiconductor, for example, by doping trivalent elements such as boron and potassium.

The donor can be formed of an N-type semiconductor, for example, by doping pentavalent elements such as phosphorus, arsenic, and antimony.

Moreover, the solar cell 100b can further include a first electrode provided on the acceptor and a second electrode provided between the donor and the planarization layer 103. In this case, the first electrode instead of the acceptor can be connected to the power supply unit 500 through the first electrode line PL1, and the second electrode instead of the donor can be connected to the power supply unit 500 through the second electrode line PL2.

Furthermore, a light absorbing layer can be further provided between the acceptor and the donor for effective light absorption.

The light absorbing layer can be formed by using single crystalline silicon (Si), amorphous silicon (a-Si), or at least one of a silicon nitride (SiNx) and a silicon oxide (SiO₂).

That is, the solar cell 100b can include a structure of any one of various types of solar cells currently used as solar panel.

In this case, the remaining elements of the light emitting display panel 100 illustrated in FIG. 6 except for the solar cell 100b can be included in the light emitting device unit 100a.

To provide an additional description, the solar cell 100b can be provided inside the light emitting device unit 100a, for example, between the planarization layer 103 and the insulation layer 105, and can include any one of the currently used solar cell structures.

Next, the insulation layer 105 can be provided on the solar cell 100b.

The insulation layer 105 can include at least one of aluminum oxide (Al₂O₃), a silicon nitride (SiNx), and a silicon oxide (SiO₂).

The insulation layer 105 can be formed of at least one layer.

Next, the selective reflecting metal RL can be provided in the insulation layer 105. For example, the selective reflecting metal RL can be provided on an upper surface of the insulation layer 105, as shown in FIG. 6.

For example, the selective reflecting metal RL can include a first selective reflecting metal (or red selective reflecting metal) RRL corresponding to the first anode (or red anode) RAN, a second selective reflecting metal (or green selective reflecting metal) GRL corresponding to the second anode (or green anode) GAN, and a third selective reflecting metal (or blue selective reflecting metal) BRL corresponding to the third anode (or blue anode) BAN, as shown in FIG. 6.

Hereinafter, for convenience of description, the first selective reflecting metal, the second selective reflecting metal, and the third selective reflecting metal can be described using the reference numerals of the red selective reflecting metal RRL, the green selective reflecting metal GRL, and the blue selective reflecting metal BRL. In particular, a light emitting display apparatus according to one or more embodiments of the present disclosure is described using the red selective reflecting metal RRL, the green selective reflecting metal GRL, and the blue selective reflecting metal BRL.

However, in the following description, if the first selective reflecting metal (or red selective reflecting metal) RRL, the second selective reflecting metal (or green selective reflecting metal) GRL, and the third selective reflecting metal (or blue selective reflecting metal) BRL need not be distinguished, the first selective reflecting metal (or red selective reflecting metal) RRL, the second selective reflecting metal (or green selective reflecting metal) GRL, and the third selective reflecting metal (or blue selective reflecting metal) BRL can be represented as a selective reflecting metal RL.

The selective reflecting metal RL can perform a function of reflecting a first color light, a second color light, and a third color light in a direction of the light emitting device ED among the light transmitted from the light emitting devices EL, and transmitting the remaining color light in the direction of the solar cell 100b.

In this case, light transmitted from the light emitting devices ED can include light generated from the light emitting device ED and external light introduced from the outside of the light emitting display panel.

Accordingly, the selective reflecting metal RL can reflect the first color light, the second color light, and the third color light in the direction of the light emitting device among the light included in the external light, and the remaining color light can be transmitted in the direction of the solar cell 100b.

The first color light can be light of one color among red, green, and blue. The second color light can be light of one color among red, green, and blue, and can be light of a different color from the first color light and the third color light. The third color light can be light of one color among red, green, and blue, and can be light of a different color from the first color light and the second color light.

For example, the first color light can be a red light, the second color light can be a green light, and the third color light can be a blue light. However, each of the first color light, the second color light, and the third color light are not limited to the above color, and can have any one of various colors.

Hereinafter, a light emitting display apparatus according to one or more embodiments of the present disclosure will be described using red light, green light, and blue light for convenience of description.

However, in the following description, if red light, green light, and blue light need not be distinguished, red light, green light, and blue light can be represented as color light.

For example, as illustrated in FIG. 6, when the selective reflecting metals RRL, GRL, and BRL are provided in the red pixel R, the green pixel G, and the blue pixel B, each of the selective reflecting metals RRL, GRL, and BRL can reflect red light LR, green light LG, and blue light LB, and transmits light other than red light LR, green light LG, and blue light LB, as shown in FIG. 7.

That is, as illustrated in FIG. 7, the reflectance of selective reflecting metals RRL, GRL, and BRL in the wavelength band including red light LR, green light LG, and blue light LB is greater than the reflectance in the rest of the wavelength band.

Also, as illustrated in FIG. 8, the transmittance of selective reflecting metals RRL, GRL, and BRL in the wavelength band including red light LR, green light LG, and blue light LB is smaller than that of selective reflecting metals RRL, GRL, and BRL in the rest of the wavelength band.

To provide an additional description, each of the selective reflecting metals RRL, GRL, and BRL can reflect light in the wavelength band including red light LR, light in the wavelength band including green light LG, and light in the wavelength band including blue light LB, and transmit light in other wavelength bands.

As described above, the red light LR, the green light LG, and the blue light LB reflected from each of the selective reflecting metals RRL, GRL, and BRL can be output to the outside through the cathode CA.

That is, according to a light emitting display apparatus according to one or more embodiments of the present disclosure, the red light LR, the green light LG, and the blue light LB generated in the light emitting device ED and transmitted toward the anode AN, and the red light LR, the green light LG, and the blue light LB included in the external light can be reflected from the selective reflecting metals RRL, GRL, and BRL and output to the outside through the cathode CA. Therefore, the luminance of light output from the light emitting display apparatus can be improved.

Moreover, the remaining light passing through the selective reflecting metals RRL, GRL, and BRL can flow into the solar cell 100b, and the solar cell 100b can generate power using the light transmitted through the selective reflecting metals RRL, GRL, and BRL.

That is, the solar cell 100b can generate power by using light generated by the light emitting device ED and external light introduced from the outside of the light emitting display panel 100. Therefore, the amount of power generated by the solar cell can be increased.

To this end, each of the selective reflecting metals RRL, GRL, and BRL can include at least three layers, for example, a first metal, an intermediate layer provided on the first metal, and a second metal provided on the intermediate layer.

In this case, the first metal and the second metal can be silver (Ag) or indium tin oxide (ITO).

The intermediate layer can be any one of a silicon nitride (SiNx), a silicon oxide (SiO₂), an indium zinc oxide (IZO), an indium tin oxide (ITO), a zinc oxide (ZnO), silver (Ag), a monomer, and an organic material. Particularly, according to the results of various simulations and tests, when a refractive index of the intermediate layer is 1.5 to 2.5, reflectance of the red light LR, the green light LG, and the blue light LB is the greatest and transmittance of the remaining light is the greatest.

Therefore, the intermediate layer can be formed to have a refractive index of any one of 1.5 to 2.5.

For example, the selective reflecting metal can be formed by sequentially stacking silver (Ag), organic material, and silver (Ag), can be formed by sequentially stacking ITO, Ag, and ITO, and in addition to this, can be formed in various stacked structures using the materials described above.

In particular, when the first metal and the second metal configuring the selective reflecting metal are silver (Ag), the two layers formed of silver (Ag) can have the same thickness.

Also, when the first metal and the second metal are silver (Ag), the thickness of the first metal can be any one of 15 to 25 nm, the thickness of the second metal can be any one of 15 to 25 nm, and the thickness of the intermediate layer can be any one of 980 to 1000 nm.

Next, an anode configuring the light emitting device ED can be provided on the selective reflecting metal RL.

For example, a red anode RAN can be provided on the red selective reflecting metal RRL, a green anode GAN can be provided on the green selective reflecting metal GRL, and a blue anode BAN can be provided on the blue selective reflecting metal BRL.

To provide an additional description, the selective reflecting metal RL and the anode AN contact each other.

In this case, the anode AN can be formed of a transparent metal such as an indium tin oxide (ITO).

Next, the bank BK can be provided between the two anodes AN.

The bank BK covers the ends of the anodes AN, and light can be output to the outside through an area of the anode AN not covered by the bank BK (hereinafter, referred to as an opening portion).

The bank BK can be formed of at least one of an organic material and an inorganic material.

Next, the anode AN and the bank BK are covered by the light emitting layer EL.

The light emitting layer EL, as illustrated in FIG. 6, can be provided continuously between the anodes AN, or can be provided independently like the anode AN.

Next, the light emitting layer EL is covered by the cathode CA.

Finally, the encapsulation layer 107 can be provided on the cathode CA. The encapsulation layer 107 can be formed of at least one layer.

Also, a color filter can be provided on the cathode CA. The color filter can be provided on the encapsulation layer 107 or can be provided inside the encapsulation layer 107.

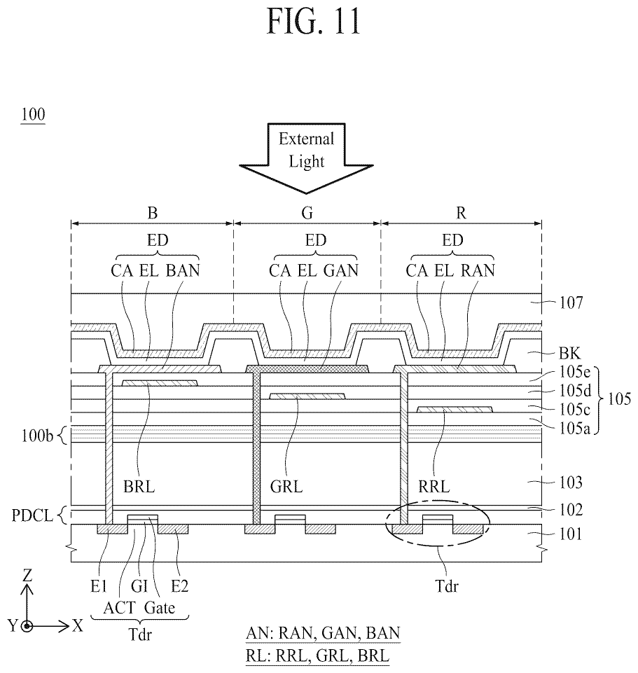

FIGS. 9 to 11 are other diagrams illustrating a cross-sectional surface of a light emitting display panel applied to a light emitting display apparatus according to one or more embodiments of the present disclosure. In the following descriptions, details which are the same as or similar to details described with reference to FIGS. 6 to 8 are omitted or briefly described.

As described above, the light emitting display panel 100 applied to a light emitting display apparatus according to one or more embodiments of the present disclosure includes the pixel driving circuit layer PDCL, the planarization layer 103, the solar cell 100b, the insulation layer 105, the selective reflecting metal RL, and the light emitting devices ED, and the selective reflecting metal RL can include at least three layers.

In this case, as illustrated in FIGS. 9 to 11, the selective reflecting metal RL can be spaced apart from the anode AN configuring the light emitting device ED, and an auxiliary insulation layer configuring the insulation layer 105 can be provided between the selective reflecting metal RL and the anode AN. The insulation layer 105 can include a first auxiliary insulation layer 105a and a second auxiliary insulation layer 105b. For example, the second auxiliary insulation layer 105b can be provided between the selective reflecting metal RL and the anode AN.

For example, in the light emitting display panel 100 illustrated in FIG. 6, the anode AN is provided on the selective reflecting metal RL, and thus the selective reflecting metal RL and the anode AN are in contact with each other. However, in the light emitting display panel 100 illustrated in FIGS. 9 to 11, the selective reflecting metal RL can be spaced apart from the anode AN.

First, referring to FIGS. 9 to 11, the light emitting devices ED can include a first color light emitting device, a second color light emitting device, and a third color light emitting device.

For example, the first color light emitting device can be a light emitting device ED that outputs red light, the second color light emitting device can be a light emitting device ED that outputs green light, and the third color light emitting device can be a light emitting device ED that outputs blue light.

The first color light emitting device includes a first anode RAN, the second color light emitting device includes a second anode GAN, and the third color light emitting device includes a third anode BAN.

In this case, the selective reflecting metal RL can include a first selective reflecting metal RRL provided at a lower end of the first anode RAN, a second selective reflecting metal GRL provided at a lower end of the second anode GAN, and a third selective reflecting metal BRL provided at a lower end of the third anode BAN.

As described above, the first selective reflecting metal can be the red selective reflecting metal RRL, the second selective reflecting metal can be the green selective reflecting metal GRL, and the third selective reflecting metal can be the blue selective reflecting metal BRL.

To provide an additional description, the red selective reflecting metal RRL can be provided at the lower end of the red anode RAN to be spaced apart from the red anode RAN, the green selective reflecting metal GRL can be provided at the lower end of the green anode GAN to be spaced apart from the green anode GAN, and the blue selective reflecting metal BRL can be provided at the lower end of the blue anode BAN to be spaced apart from the blue anode BAN.

For example, as illustrated in FIG. 9, the first auxiliary insulation layer 105a can be provided on the solar cell 100b. The first selective reflecting metal RRL, the second selective reflecting metal GRL, and the third selective reflecting metal BRL can be provided on the first auxiliary insulation layer 105a. The first selective reflecting metal RRL, the second selective reflecting metal GRL, and the third selective reflecting metal BRL can be covered by the second auxiliary insulation layer 105b. The red anode RAN, the green anode GAN, and the blue anode BAN can be provided on the second auxiliary insulation layer 105b.

Next, as described above, the first auxiliary insulation layer 105a can be provided on the solar cell 100b, the first selective reflecting metal RRL, the second selective reflecting metal GRL, and the third selective reflecting metal BRL can be provided on the first auxiliary insulation layer 105a, the first selective reflecting metal RRL, the second selective reflecting metal GRL, and the third selective reflecting metal BRL can be covered by the second auxiliary insulation layer 105b, and the red anode RAN, the green anode GAN, and the blue anode BAN can be provided on the second auxiliary insulation layer 105b.

In particular, as illustrated in FIG. 10, the first selective reflecting metal RRL, the second selective reflecting metal GRL, and the third selective reflecting metal BRL can be connected to each other and can be provided on first auxiliary insulation layer 105a in the form of a plate.

In this case, a connection line connecting the driving transistor Tdr and the anode AN can be provided in the insulation layer 105, and to this end, a contact hole can be provided in the insulation layer 105.

In order to prevent the selective reflecting metal RL formed in one plate shape from contacting the connection line, the selective reflecting metal RL may not be formed around the contact hole.

For example, one plate-shaped selective reflecting metal RL can be, as illustrated in FIG. 10, provided on the first auxiliary insulation layer 105a, and one plate-shaped selective reflecting metal RL can be covered by the second auxiliary insulation layer 105b.

In this case, the one plate-shaped selective reflecting metal RL is not clearly divided into the first selective reflecting metal RRL, the second selective reflecting metal GRL, and the third selective reflecting metal BRL.

However, an area provided at a lower end of the first anode RAN among the plate-shaped selective reflecting metal RL can be the first selective reflecting metal RRL, an area provided at a lower end of the second anode GAN among the plate-shaped selective reflecting metal RL can be the second selective reflecting metal GRL, and an area provided at a lower end of the third anode BAN among the plate-shaped selective reflecting metal RL can be the third selective reflecting metal BRL.

To provide an additional description, because power is not supplied to the first selective reflecting metal RRL, the second selective reflecting metal GRL, and the third selective reflecting metal BRL and does not affect the driving of the light emitting devices, the first selective reflecting metal RRL, the second selective reflecting metal GRL, and the third selective reflecting metal BRL can be formed in a single plate shape.

In this case, the selective reflecting metal RL in the form of one plate can be used as the first electrode provided on the acceptor.

That is, the first selective reflecting metal RRL, the second selective reflecting metal GRL, and the third selective reflecting metal BRL can be used as the first electrode configuring the solar cell 100b because the first selective reflecting metal RRL, the second selective reflecting metal GRL, and the third selective reflecting metal BRL do not affect the driving of the light emitting devices.

Finally, as described above, the first auxiliary insulation layer 105a can be provided on the solar cell 100b, the first selective reflecting metal RRL, the second selective reflecting metal GRL, and the third selective reflecting metal BRL can be provided on the first auxiliary insulation layer 105a, the first selective reflecting metal RRL, the second selective reflecting metal GRL, and the third selective reflecting metal BRL can be covered by a second auxiliary insulation layer 105b, and the red anode RAN, the green anode GAN, and the blue anode BAN can be provided on the second auxiliary insulation layer 105b.

In particular, as illustrated in FIG. 11, a distance between the first anode RAN and the first selective reflecting metal RRL, a distance between the second anode GAN and the second selective reflecting metal GRL, and a distance between the third anode BAN and the third selective reflecting metal BRL can be different from each other.

For example, the distance between the first anode RAN and the first selective reflecting metal RRL can be greater than the distance between the second anode GAN and the second selective reflecting metal GRL, and the distance between the second anode GAN and the second selective reflecting metal GRL can be greater than the distance between the third anode BAN and the third selective reflecting metal BRL.

In FIG. 11, The insulation layer 105 can include a first auxiliary insulation layer 105a, a third auxiliary insulation layer 105c, a fourth auxiliary insulation layer 105d, and a fifth auxiliary insulation layer 105e. In this case, the first auxiliary insulation layer 105a can be provided on the solar cell 100b, the first selective reflecting metal RRL can be provided on the first auxiliary insulation layer 105a, the first selective reflecting metal RRL can be covered by a third auxiliary insulation layer 105c, the second selective reflecting metal GRL can be provided on the third auxiliary insulation layer 105c, the second selective reflecting metal GRL can be covered by a fourth auxiliary insulation layer 105d, the third selective reflecting metal BRL can be provided on the fourth auxiliary insulation layer 105d, the third selective reflecting metal BRL can be covered by a fifth auxiliary insulation layer 105e, and the first anode RAN, the second anode GAN, and the third anode BAN can be provided on the fifth auxiliary insulation layer 105e.

The distance between the anode AN and the selective reflecting metal RL can be variously set in consideration of a microcavity effect.

For example, the selective reflecting metal RL can be provided at the lower end of the anode AN to increase the extraction efficiency of blue light output from the blue pixel B, green light output from the green pixel G, and red light output from the red pixel R.

For example, due to the microcavity structure between the blue anode BAN and the blue selective reflecting metal BRL, the light output from the light emitting device ED including the blue anode BAN can contain more blue light than other colors of light. In this case, when the light output from the light emitting device ED passes through the blue color filter, only blue light can be output to the outside through the blue color filter. Therefore, when the micro cavity structure is used, more blue light can be output to the outside through the blue color filter.

Furthermore, due to the microcavity structure between the green anode GAN and the green selective reflecting metal GRL, more green light can be output to the outside through the green color filter.

Furthermore, due to the microcavity structure between the red anode RAN and the red selective reflecting metal RRL, more red light can be output to the outside through the red color filter.

To this end, the distance between the red anode RAN and the red selective reflecting metal RRL, the distance between the green anode GAN and the green selective reflecting metal GRL, and the distance between the blue anode BAN and the blue selective reflecting metal BRL can be set differently.

For example, as described above with reference to FIG. 11, the distance between the first anode RAN and the first selective reflecting metal RRL can be greater than the distance between the second anode GAN and the second selective reflecting metal GRL, and the distance between the second anode GAN and the second selective reflecting metal GRL can be greater than the distance between the third anode BAN and the third selective reflecting metal BRL.

In this case, there can be no gap between the third anode BAN and the third selective reflecting metal BRL, for example, there can be no gap between the blue anode BAN and the blue selective reflecting metal BRL. To provide an additional description, the blue anode BAN can be provided on the blue selective reflecting metal BRL. In this case, the fifth auxiliary insulation layer 105e can be omitted.

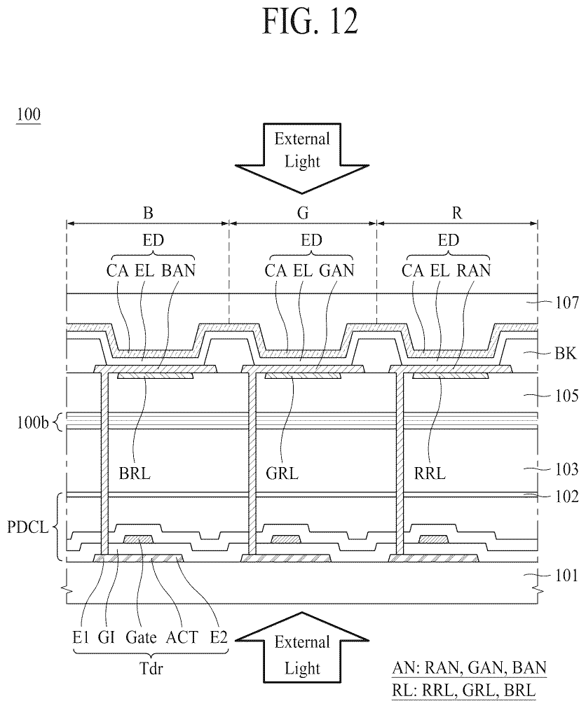

FIG. 12 is another diagram illustrating a cross-section surface of a light emitting display panel applied to a light emitting display apparatus according to one or more embodiment of the present disclosure. In the following descriptions, details which are the same as or similar to details described with reference to FIGS. 6 to 11 are omitted or briefly described.

In a light emitting display panels described above, as illustrated in FIGS. 6 and 9 to 11, the solar cell 100b can generate power using external light introduced from the outside through the cathode CA and light generated from the light emitting devices ED.

That is, the substrate 101 formed of a semiconductor is used in the light emitting display panel 100 illustrated in FIG. 6 and FIG. 9 to FIG. 11. Therefore, light introduced into the lower surface of the substrate 101 cannot be introduced into the solar cell 100b through the substrate 101.

Furthermore, if an opaque glass substrate, an opaque plastic substrate, or an opaque flexible substrate, as well as a substrate 101 formed of a semiconductor, is used as the substrate 101, the light flowing into the lower surface of the substrate 101 cannot flow into the solar cell 100b through the substrate 101.

However, if a transparent substrate, such as a transparent glass substrate, a transparent plastic substrate, or a transparent flexible substrate, is used as the substrate 101, the solar cell 100b can, as illustrated FIG. 12, generate power using external light introduced through the transparent substrate.

To provide an additional description, the light emitting display panel 100 illustrated in FIG. 12 can have the same structure as that of the light emitting display panel 100 illustrated in FIG. 6 and FIGS. 9 to 11, except that a transparent substrate is used as the substrate 101.

For example, a light emitting display panel 100 applied to an electronic device having a structure in which light can be introduced through the substrate 101 and the cathode CA can be formed using a transparent substrate 101, as illustrated in FIG. 12.

However, the light emitting display panel 100 applied to an electronic device having a structure in which light can only be introduced through the cathode CA can be, as illustrated in FIG. 6 and FIGS. 9 to 11, formed using the substrate 101 formed of semiconductors, or an opaque glass substrate, an opaque plastic substrate, or an opaque flexible substrate.

According to a light emitting display apparatus according to one or more embodiments of the present disclosure described above, while the light emitting display panel 100 outputs an image, the light emitting display panel 100 can generate power by using light generated in the light emitting device ED and external light.

Therefore, even if power is not supplied from the outside, the light emitting display apparatus can be driven using power generated in the light emitting display panel 100.

The features of the light emitting display apparatus according to one or more embodiments of the present disclosure are briefly summarized as follows.

A light emitting display apparatus according to one or more embodiments of the present disclosure includes a pixel driving circuit layer with pixel driving circuits; a planarization layer covering the pixel driving circuit layer; a solar cell on the planarization layer; an insulation layer on the solar cell; a selective reflecting metal in the insulation layer; and light emitting devices on the insulation layer, wherein the selective reflecting metal includes at least three layers.

The selective reflecting metal reflects a first color light, a second color light, and a third color light in a direction of light transmitted from the light emitting device of the plurality of light emitting devices, and the selective reflecting metal transmits remaining color light in the direction of the solar cell.

The selective reflecting metal includes: a first metal; an intermediate layer provided on the first metal; and a second metal provided on the intermediate layer.

The first metal and the second metal are silver (Ag) or indium tin oxide (ITO).

The intermediate layer is any one of silicon nitride (SiNx) (film), silicon oxide (SiO2), indium zinc oxide (IZO), indium tin oxide (ITO), zinc oxide (ZnO), silver (Ag), a monomer, and an organic material.

A refractive index of the intermediate layer is in a range from 1.5 to 2.5.

The insulation layer includes at least one of aluminum oxide (Al₂O₃), silicon nitride (SiNx), and silicon oxide (SiO2).

The selective reflecting metal is provided on the insulation layer, and an anode configuring a light emitting device is provided on the selective reflecting metal.

The insulation layer includes a first auxiliary insulation layer and a second auxiliary insulation layer, the selective reflecting metal is spaced apart from an anode configuring a light emitting device, and the second auxiliary insulation layer is provided between the selective reflecting metal and the anode.

The light emitting devices include a first color light emitting device, a second color light emitting device, and a third color light emitting device, the first color light emitting device includes a first anode, the second color light emitting device includes a second anode, the third color light emitting device includes a third anode, and the selective reflecting metal includes a first selective reflecting metal provided at a lower end of the first anode, a second selective reflecting metal provided at a lower end of the second anode, and a third selective reflecting metal provided at a lower end of the third anode.

The first auxiliary insulation layer is provided on the solar cell; the first selective reflecting metal, the second selective reflecting metal, and the third selective reflecting metal are provided on the first auxiliary insulation layer; and the first selective reflecting metal, the second selective reflecting metal, and the third selective reflecting metal are connected to each other.

A contact hole is provided in the first and second auxiliary insulation layers, and no selective reflecting metal is formed around the contact hole. A distance between the first anode and the first selective reflecting metal, a distance between the second anode and the second selective reflecting metal, and a distance between the third anode and the third selective reflecting metal are different from each other.

The solar cell generates power by using the light that is transmitted from the light emitting devices and transmitted through the selective reflecting metal. The pixel driving circuit layer is provided on a semiconductor substrate, a glass substrate, a plastic substrate, or a transparent substrate.

When a substrate on which the pixel driving circuit is provided is a transparent substrate, the solar cell generates power by using light introduced through the transparent substrate.

When the first metal and the second metal are silver (Ag), a thickness of the first metal is in a range of 15 nm to 25 nm, a thickness of the second metal is in a range of 15 nm to 25 nm, and a thickness of the intermediate layer is in a range of 980 nm to 1000 nm.

The light emitting display apparatus according to one or more embodiments of the present disclosure can be applied to all electronic devices including a light emitting display panel. For example, the light emitting display apparatus according to one or more embodiments of the present disclosure can be applied to a virtual reality (VR) device, an augmented reality (AR) device, a mobile device, a video phone, a smart watch, a watch phone, or a wearable device, foldable device, rollable device, bendable device, flexible device, curved device, electronic notebook, e-book, PMP (portable multimedia player), PDA (personal digital assistant), MP3 player, mobile medical device, desktop PC, laptop PC, netbook computer, workstation, navigation, car navigation, vehicle display devices, televisions, wall paper display devices, signage devices, game devices, laptops, monitors, cameras, camcorders, and home appliances.

In a light emitting display apparatus according to one or more embodiments of the present disclosure, a solar cell is integrated into a light emitting display panel. Therefore, even if power is not supplied from the outside, a light emitting display apparatus can be used for a long time.

For example, when a light emitting display apparatus according to one or more embodiments of the present disclosure is applied to an electronic product that a user can carry, such as a smartphone, tablet computer, electronic pad, wearable device, and watch phone, a user can use an electronic product for a long time without charging the electronic product.

In particular, when a light emitting display apparatus according to one or more embodiments of the present disclosure is applied to electronic products such as virtual reality (VR) devices and augmented reality (AR) devices manufactured in the form of glasses, charging by the solar cell can be performed together when the electronic product is used. Therefore, a user can use the virtual reality (VR) device and augmented reality (AR) device in the form of glasses for a long time without charging.

In this case, because the virtual reality (VR) device and augmented reality (AR) device do not need to be connected to a battery, the virtual reality (VR) device and the augmented reality (AR) device do not need to be connected to a wire to connect the virtual reality (VR) device and the augmented reality (AR) device to a battery.

Therefore, a user can experience virtual reality (VR) and augmented reality (AR) for a long time using only virtual reality (VR) devices and augmented reality (AR) devices in the form of glasses without auxiliary devices such as batteries and wires.

That is, according to a light emitting display apparatus according to one or more embodiments of the present disclosure, power consumption of power supplied from the outside can be reduced, and an image of high luminance can be provided.

The above-described feature, structure, and effect of the present disclosure are included in one or more embodiments of the present disclosure, but are not limited to only one embodiment. Furthermore, the feature, structure, and effect described in one or more embodiments of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

What is claimed is:

1. A light emitting display apparatus, comprising:
a pixel driving circuit layer including a plurality of pixel driving circuits;
a planarization layer that covers the pixel driving circuit layer;
a solar cell on the planarization layer;
an insulation layer on the solar cell;
a selective reflecting metal in the insulation layer, the selective reflecting metal including at least three metal layers; and
a plurality of light emitting devices on the insulation layer.

2. The light emitting display apparatus of claim 1, wherein the selective reflecting metal reflects light of a first color, light of a second color, and light of a third color in a direction of light transmitted from a light emitting device of the plurality of light emitting devices, and the selective reflecting metal transmits remaining color light in a direction of the solar cell.

3. The light emitting display apparatus of claim 1, wherein the selective reflecting metal includes:
a first metal;
an intermediate layer on the first metal; and
a second metal on the intermediate layer.

4. The light emitting display apparatus of claim 3, wherein the first metal and the second metal are silver or indium tin oxide.

5. The light emitting display apparatus of claim 4, wherein the intermediate layer is one of a silicon nitride, silicon oxide, indium zinc oxide, indium tin oxide, zinc oxide, silver, a monomer, and an organic material.

6. The light emitting display apparatus of claim 3, wherein a refractive index of the intermediate layer is in a range from 1.5 to 2.5.

7. The light emitting display apparatus of claim 1, wherein the insulation layer includes at least one of aluminum oxide, silicon nitride, and silicon oxide.

8. The light emitting display apparatus of claim 1, wherein the selective reflecting metal is on the insulation layer, and
wherein an anode that configures a light emitting device of the plurality of light emitting devices is on the selective reflecting metal.

9. The light emitting display apparatus of claim 1, wherein the insulation layer includes a first auxiliary insulation layer and a second auxiliary insulation layer,
wherein the selective reflecting metal is spaced apart from an anode that configures a light emitting device of the plurality of light emitting devices, and
the second auxiliary insulation layer is between the selective reflecting metal and the anode.

10. The light emitting display apparatus of claim 9, wherein the plurality of light emitting devices include a first color light emitting device, a second color light emitting device, and a third color light emitting device,
wherein the first color light emitting device includes a first anode, the second color light emitting device includes a second anode, and the third color light emitting device includes a third anode, and
wherein the selective reflecting metal includes a first selective reflecting metal at a lower end of the first anode, a second selective reflecting metal at a lower end of the second anode, and a third selective reflecting metal at a lower end of the third anode.

11. The light emitting display apparatus of claim 10, wherein the first auxiliary insulation layer is on the solar cell,
wherein the first selective reflecting metal, the second selective reflecting metal, and the third selective reflecting metal are on the first auxiliary insulation layer, and
wherein the first selective reflecting metal, the second selective reflecting metal, and the third selective reflecting metal are connected to each other.

12. The light emitting display apparatus of claim 10, wherein a first distance between the first anode and the first selective reflecting metal, a second distance between the second anode and the second selective reflecting metal, and a third distance between the third anode and the third selective reflecting metal are different from each other.

13. The light emitting display apparatus of claim 1, wherein the pixel driving circuit layer is on a semiconductor substrate, a glass substrate, a plastic substrate, or a transparent substrate.

14. The light emitting display apparatus of claim 13, wherein a substrate including a pixel driving circuit of the plurality of pixel driving circuits is a transparent substrate, and the solar cell generates power by using light that passes through the transparent substrate.

15. The light emitting display apparatus of claim 4, wherein the first metal and the second metal are silver, a thickness of the first metal is in a range from 15 nm to 25 nm, a thickness of the second metal is in a range from 15 nm to 25 nm, and a thickness of the intermediate layer is in a range from 980 nm to 1000 nm.

16. The light emitting display apparatus of claim 11, wherein a contact hole is provided in the first auxiliary insulation layer and the second auxiliary insulation layer, and no selective reflecting metal is formed around the contact hole.

17. The light emitting display apparatus of claim 2, wherein the solar cell generates power by using the light that is transmitted from the plurality of light emitting devices and transmitted through the selective reflecting metal.
